(19) United States
(12) Patent Application Publication
(10) Pub. No.: US 2016/0148983 A1
(43) Pub. Date: May 26, 2016

(54) ORGANIC LIGHT-EMITTING DIODE DISPLAY AND MANUFACTURING METHOD THEREOF

(71) Applicant: Samsung Display Co., Ltd., Yon gin-City (KR)

(72) Inventors: Myoung Geun Cha, Seoul (KR); Dong Jo Kim, ,Suwon-si (KR); Yoon Ho Khang, Yongin-si (KR); Jong Chan Lee, Suwon-si (KR)

(21) Appl. No.: 14/708,070

(22) Filed: May 8, 2015

(30) Foreign Application Priority Data
Nov. 21, 2014 (KR) 10-2014-0163367

(51) Int. Cl. H01L 27/32; H01L 21/223; H01L 21/311

(52) U.S. Cl. CPC H01L 27/3262; H01L 27/3248; H01L 27/3258; H01L 21/31116; H01L 21/2236; H01L 2227/323

(57) ABSTRACT

An OLED display and a method of manufacturing the same are disclosed. In one aspect, the OLED display includes a substrate and a semiconductor layer formed over the substrate, wherein the semiconductor layer includes a channel and a contact region formed on opposing sides of the channel. The display also includes an insulating layer formed over the semiconductor layer and having a contact hole exposing the contact region, and an OLED formed over the insulating layer, wherein the OLED is electrically connected to the contact region through the contact hole, and wherein at least a portion of the contact hole is formed directly above the contact region.

### CROSS-REFERENCE TO RELATED APPLICATION

This application claims priority to and the benefit of Korean Patent Application No. 10-2014-0163367 filed in the Korean Intellectual Property Office on Nov. 21, 2014, the entire contents of which are incorporated herein by reference.

### BACKGROUND

1. Field

The described technology generally relates to an organic light-emitting diode display and a manufacturing method thereof.

2. Description of the Related Technology

An organic light-emitting diode (OLED) includes two electrodes and an organic light emitting layer positioned therebetween. Electrons injected from a cathode electrode and holes injected from an anode electrode are combined in the organic light emitting layer to form excitons. Light is emitted is emitted from the discharge of energy by the excitons.

An OLED display includes a matrix of pixels including an OLED formed of the cathode, the anode, and the organic light emitting layer. A plurality of thin film transistors and capacitors for driving the OLED are formed in each pixel. To form the transistor and the capacitor, a photolithography process including a dry etching process, a wet etching process, and a doping process of doping the semiconductor are required.

### SUMMARY OF CERTAIN INVENTIVE ASPECTS

One inventive aspect is a method of manufacturing an OLED display for improving efficiency through simplification of the manufacturing process.

Another aspect is an OLED display that includes: a substrate; a semiconductor formed on the substrate and including a channel that is channel-doped, and a contact doping region positioned at both sides of the channel and contact-doped; an insulating layer covering the semiconductor and having a contact hole exposing the contact doping region; and an OLED formed on the insulating layer, wherein the OLED is connected to the contact doping region through the contact hole, and a position of the contact hole corresponds to a position of the contact doping region.

A lowest boundary of the contact hole can accord with an upper most boundary of the contact doping region.

The channel can include a switching channel and a driving channel separated from each other, the insulating layer can include a gate insulating layer covering the semiconductor and an interlayer insulating layer covering the gate insulating layer, a driving gate electrode formed between the gate insulating layer and the interlayer insulating layer and overlapping a part of the driving channel can be further included, and the length of the driving gate electrode can be shorter than the length of the driving channel.

A driving gate electrode formed between the gate insulating layer and the interlayer insulating layer and overlapping a part of the driving channel can be further included, and the length of the switching gate electrode can be shorter than the length of the switching channel.

A passivation layer formed on the interlayer insulating layer can be further included, and the OLED can include a pixel electrode formed on the passivation layer and connected to the semiconductor, an organic emission layer formed on the pixel electrode, and a common electrode formed on the organic emission layer.

Another aspect is a manufacturing method of an OLED display that includes: forming a semiconductor on a substrate; forming an insulating layer covering the semiconductor; etching the insulating layer to form a contact hole exposing a part of the semiconductor; and performing a contact doping process to form a contact doping region at a part of the semiconductor exposed by the contact hole.

The forming of the contact hole and the forming of the contact doping region can be performed with the same plasma processing device.

The dry etching process can be performed by using a fluorine series gas in the plasma processing device in the forming of the contact hole, and the ion doping process can be performed by using a compound of Group 3 ions and a fluorine series gas in the plasma processing device in the forming of the contact doping region.

The position of the contact hole can correspond to the position of the contact doping region.

The method can further include performing a channel doping process to form the channel in the semiconductor after forming the semiconductor.

Another aspect is an organic light-emitting diode (OLED) display, comprising a substrate and a semiconductor layer formed over the substrate, wherein the semiconductor layer includes a channel and a contact region formed on opposing sides of the channel. The display also comprises an insulating layer formed over the semiconductor layer and having a contact hole exposing the contact region, and an OLED formed over the insulating layer, wherein the OLED is electrically connected to the contact region through the contact hole, and wherein at least a portion of the contact hole is formed directly above the contact region.

In the above display, the contact hole has top and bottom portions opposing each other, wherein the contact region has top and bottom portions opposing each other, and wherein the bottom portion of the contact hole is connected to the top portion of the contact region.

In the above display, the width of the bottom portion of the contact hole and the width of the top portion of the contact region are substantially the same.

In the above display, the width of the contact hole gradually increases from the bottom portion to the top portion thereof.

The above OLED display further comprises a driving gate electrode formed over the channel, wherein the channel includes a switching channel and a driving channel separated from each other, wherein the insulating layer includes a gate insulating layer formed over the semiconductor layer and an interlayer insulating layer formed over the gate insulating layer, wherein the driving gate electrode is formed between the gate insulating layer and the interlayer insulating layer and overlapping a portion of the driving channel, and wherein the length of the driving gate electrode is less than the length of the driving channel.

The above OLED display further comprises a switching gate electrode formed between the gate insulating layer and the interlayer insulating layer and overlapping a portion of the switching channel, wherein the length of the switching gate electrode is less than the length of the switching channel.

The above OLED display further comprises a passivation layer formed over the interlayer insulating layer, wherein the OLED includes i) a pixel electrode formed over the passivation layer and electrically connected to the semiconductor layer, ii) an organic emission layer formed over the pixel electrode, and iii) a common electrode formed over the organic emission layer.

Another aspect is a method of manufacturing an organic light-emitting diode (OLED) display, comprising forming a semiconductor layer over a substrate, forming an insulating layer over the semiconductor layer, etching the insulating layer so as to form a contact hole exposing a portion of the semiconductor layer, and performing a contact doping process so as to form a contact region in a portion of the semiconductor layer exposed by the contact hole.

In the above method, the forming of the contact hole and the forming of the contact region are performed with the same plasma processing device.

In the above method, the etching is performed with a fluorine series gas in the plasma processing device, wherein the contact doping process is performed with a compound of Group 3 ions and a fluorine series gas in the plasma processing device.

In the above method, at least a portion of the contact hole is formed directly above the contact region.

The above method further comprises performing a channel doping process so as to form the channel in the semiconductor layer after forming the semiconductor layer.

In the above method, the contact hole has top and bottom portions opposing each other, wherein the contact region has top and bottom portions opposing each other, and wherein the bottom portion of the contact hole is connected to the top portion of the contact region.

In the above method, the width of the bottom portion of the contact hole and the width of the top portion of the contact region are substantially the same.

In the above method, the width of the contact hole gradually increases from the bottom portion to the top portion thereof.

Another aspect is an organic light-emitting diode (OLED) display, comprising a substrate and a driving transistor including i) a driving semiconductor layer formed over the substrate and including a driving channel having two lateral ends and ii) a driving contact region formed adjacent to the lateral ends. The display also comprises an insulating layer formed over the driving semiconductor layer and having a driving contact hole extending from the driving contact region and an OLED formed over the insulating layer and electrically connected to the driving contact region through the driving contact hole.

In the above display, at least a portion of the contact hole is formed directly above the contact region.

The above display further comprises a switching transistor including i) a switching semiconductor layer formed over the substrate and including a switching channel having two lateral ends and ii) a switching contact region formed adjacent to the lateral ends, wherein the switching transistor is electrically connected to the driving transistor.

In the above display, the driving and switching contact holes each has top and bottom portions opposing each other, wherein the driving and switching contact regions each has top and bottom portions opposing each other, wherein the bottom portions of the contact holes are respectively connected to the top portions of the contact regions, and wherein the widths of the bottom portions of the contact holes and the widths of the top portions of the contact regions are substantially the same, respectively.

In the above display, each of the widths of the driving and switching channels is respectively greater than each of the widths of the driving and switching gate electrodes.

According to at least one of the disclosed embodiments, by performing the dry etching process to form the contact hole and the ion doping process to form the contact doping region in the same plasma processing device, separate implantation can be omitted, thereby simplifying the manufacturing process.

### BRIEF DESCRIPTION OF THE DRAWINGS

FIG. 1 is a cross-sectional view of a transistor of an OLED display according to an exemplary embodiment.

FIG. 2, FIG. 3, and FIG. 4 are cross-sectional views sequentially showing a manufacturing method of an OLED display according to an exemplary embodiment.

FIG. 5 is an equivalent circuit diagram of one pixel of an OLED display according to another exemplary embodiment.

FIG. 6 is a detailed layout view of one pixel of an OLED display according to another exemplary embodiment.

FIG. 7 is a cross-sectional view taken along a line VII-VII of FIG. 6.

FIG. 8, FIG. 10, and FIG. 12 are layout views sequentially showing a manufacturing method of an OLED display according to an exemplary embodiment.

FIG. 9 is a cross-sectional view of the OLED display of FIG. 8 taken along a line IX-IX.

FIG. 11 is a cross-sectional view of the OLED display of FIG. 10 taken along a line XI-XI.

FIG. 13 is a cross-sectional view of the OLED display of FIG. 12 taken along a line XIII-XIII.

FIG. 14 is a cross-sectional view of the OLED display of FIG. 12 taken along a line XIII-XIII after the manufacturing step shown in FIG. 13.

### DETAILED DESCRIPTION OF CERTAIN INVENTIVE EMBODIMENTS

In manufacturing an OLED display, a dry etching process used to form a contact hole in a gate insulating layer and an interlayer insulating layer and an ion doping process used to make a portion of the semiconductor connected to the anode into a conductor are separately performed. Also, the dry etching process is performed by use of a dry etcher and the ion doping process is performed by use of ion implantation. The dry etching process and the ion doping process are separately performed in each device and moving the substrate can generate an unnecessary loss of time.

The present disclosure will be described more fully hereinafter with reference to the accompanying drawings, in which exemplary embodiments of the disclosure are shown. As those skilled in the art would realize, the described embodiments can be modified in various different ways, all without departing from the spirit or scope of the present disclosure.

Accordingly, the drawings and description are to be regarded as illustrative in nature and not restrictive. Like reference numerals designate like elements throughout the specification.

In addition, the size and thickness of each configuration shown in the drawings are arbitrarily shown for better understanding and ease of description, but the present disclosure is not limited thereto.

In the drawings, the thickness of layers, films, panels, regions, etc., are exaggerated for clarity. Further, in the drawings, the thickness of layers and regions are partially exaggerated for better understanding and ease of description. It will be understood that when an element such as a layer, film, region, or substrate is referred to as being “on” another element, it can be directly on the other element or intervening elements can also be present.

Further, in the specification, a statement regarding an upper part of a target portion indicates an upper part or a lower part of a target portion, rather than the target portion always being positioned at the upper side based on a gravity direction.

Further, in the specification, the phrase “in a plan view” means when an object portion is viewed from above, and the phrase “in across-section” means when a cross-section taken by vertically cutting an object portion is viewed from the side. While the inventive technology has been described with reference to the figures, it will be understood by those of ordinary skill in the art that various changes in form and details can be made therein without departing from the spirit and scope as defined by the following claims.

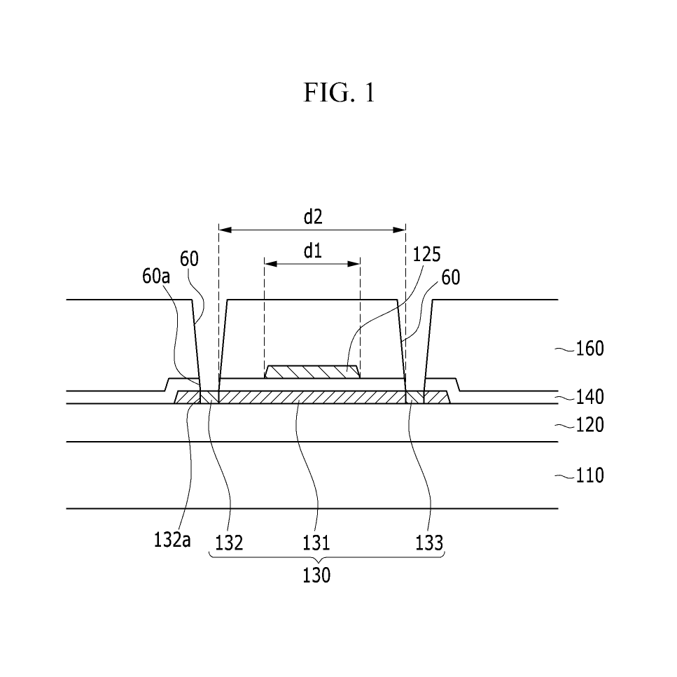

Now, an OLED display according to an exemplary embodiment will be described with reference to FIG. 1 to FIG. 4.

FIG. 1 is a cross-sectional view of a transistor of an OLED display according to an exemplary embodiment.

As shown in FIG. 1, the transistor includes a substrate 110, a semiconductor or semiconductor layer 130 formed on the substrate 110, a gate insulating layer 140 covering the semiconductor 130, a gate electrode 125 formed on the gate insulating layer 140, and an interlayer insulating layer 160 covering the gate electrode 125 and the gate insulating layer 140.

The semiconductor 130 includes a channel 131 that is channel-doped and contact doping regions or contact regions 132 and 133 that are positioned at both sides of the channel 131 and are contact-doped. The gate electrode 125 overlaps a part of the channel 131, and the contact doping regions 132 and 133 include a source region 132 and a drain region 133.

Also, the gate insulating layer 140 and the interlayer insulating layer 160 have a contact hole 60 exposing the contact doping regions 132 and 133.

The position of the contact hole 60 corresponds to the position of the contact doping regions 132 and 133. That is, a lowest boundary 60a of the contact hole 60 accords with an uppermost boundary 132a of the contact doping regions 132 and 133. For example, if a plane shape of the contact hole 60 is circular, the plane shape of the contact doping regions 132 and 133 is also circular, and if the plane shape of the contact hole 60 is quadrangular, the plane shape of the contact doping regions 132 and 133 is also quadrangular.

Further, since the contact doping regions 132 and 133 are formed without the usage of the gate electrode 125 as a doping mask, a length d1 of the gate electrode 125 is different from a length d2 of the channel 131. That is, the length d1 of the gate electrode 125 is shorter than the length d2 of the channel 131.

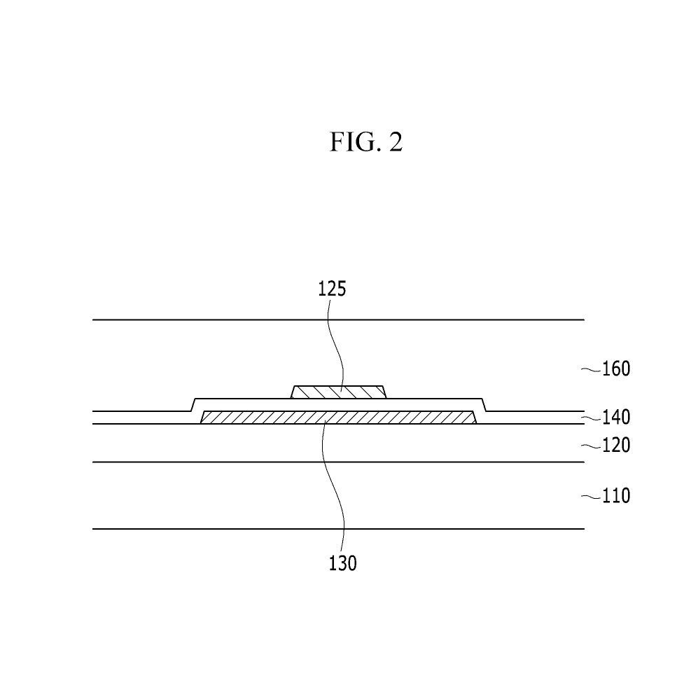

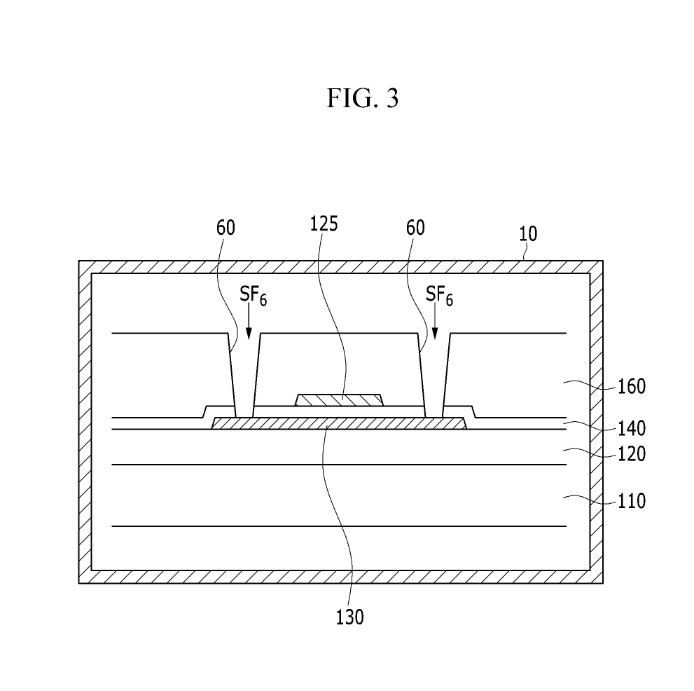

The structure of the transistor in FIG. 1 is the structure according to the manufacturing method of the OLED display. The manufacturing method of the OLED display according to an exemplary embodiment will be described with reference to FIG. 2 to FIG. 4.

FIG. 2 to FIG. 4 are cross-sectional views sequentially showing a manufacturing method of an OLED display according to an exemplary embodiment.

First, as shown in FIG. 2, the semiconductor 130 is formed on the substrate 110. The semiconductor 130 in this case is an intrinsic semiconductor that is not doped with an impurity. Also, the semiconductor 130 is subjected to a channel doping process. The semiconductor 130 in this case is an impurity semiconductor. The gate insulating layer 140 covering the semiconductor 130 is formed and the gate electrode 125 is formed on the gate insulating layer 140. The interlayer insulating layer 160 covering the gate electrode 125 is formed.

Next, as shown in FIG. 3, the gate insulating layer 140 and the interlayer insulating layer are etched to form the contact hole 60 exposing a part of the semiconductor 130. In this case, the dry etching process is performed in a plasma processing device 10 to form the contact hole 60, and a fluorine-series gas is used. As the fluorine series gas, there are SF₆ and CF₆.

Next, as shown in FIG. 4, the contact doping process is performed to form the contact doping regions 132 and 133 at the part of the semiconductor 130 exposed by the contact hole 60. In this case, the ion doping process is continuously performed in the plasma processing device 10 in which the dry etching process is performed to form the contact doping regions 132 and 133 while using a compound of Group 3 ions and a fluorine series gas. For example, the ion doping process is performed with BF₃ using boron (B) as Group 3 ions.

As described above, in the same plasma processing device, by performing the dry etching process to form the contact hole together with the ion doping process to form the contact doping region, separate implantation can be omitted such that the manufacturing process can be simplified.

However, another exemplary embodiment for the OLED display including a plurality of transistors applied with the characteristics of the present disclosure can be realized.

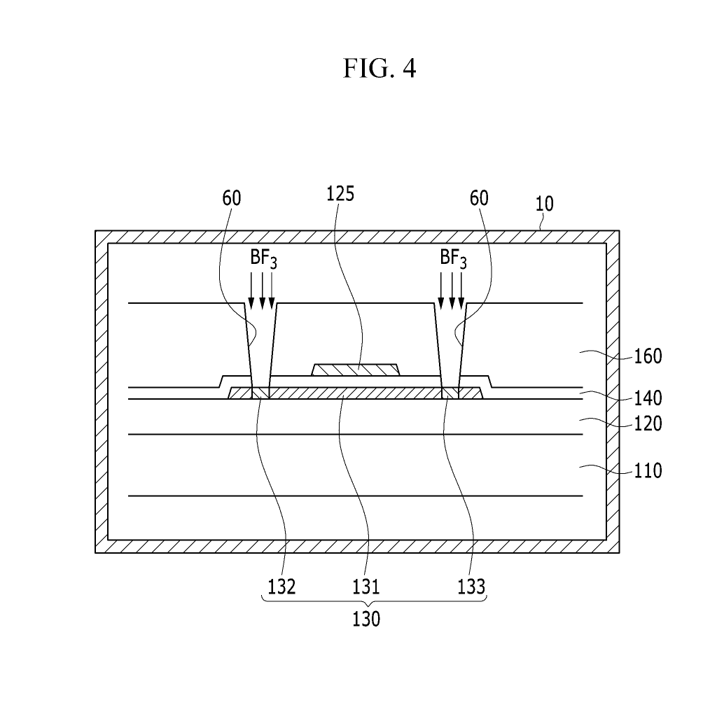

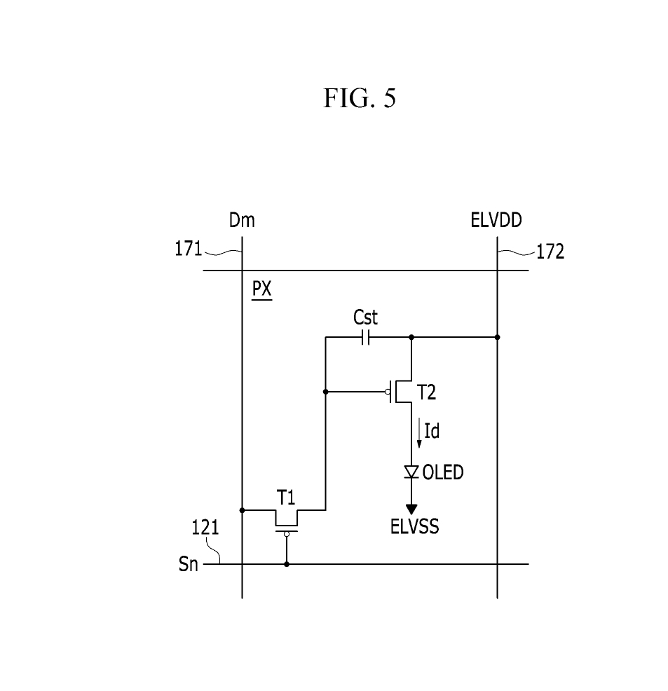

Next, the OLED display according to another exemplary embodiment will be described with reference to FIG. 5 to FIG. 7.

FIG. 5 is an equivalent circuit diagram of one pixel of an OLED display according to another exemplary embodiment.

As shown in FIG. 5, one pixel PX of the OLED display includes a plurality of signal lines 121, 171, and 172, a plurality of transistors T1 and T2 connected to the signal lines, a storage capacitor (Cst), and an OLED.

The transistors T1 and T2 include a switching transistor T1 and a driving transistor T2.

The signal lines 121 171, and 172 include a scan line 121 transmitting a scan signal Sn, a data line 171 crossing the scan line 121 and transmitting a data signal Dm, and a driving voltage line 172 transmitting a driving voltage ELVDD and being substantially parallel to the data line 171.

The switching transistor T1 has a control terminal, an input terminal, and an output terminal. The control terminal is connected to the scan line 121, the input terminal is connected to the data line 171, and the output terminal is connected to the driving thin film transistor T2. The switching thin film transistor T1 transmits the data signal Dm to the driving transistor T2 in response to the scan signal Sn.

The driving transistor T2 also has a control terminal, an input terminal, and an output terminal. The control terminal is connected to the switching transistor T1, the input terminal is connected to the driving voltage line 172, and the output terminal is connected to the OLED. A driving current Id flows through the driving transistor T2. The driving current Id has a magnitude that varies based at least in part on the voltage between the control terminal and the output terminal.

The storage capacitor Cst is connected between the control terminal and the input terminal of the driving transistor T2. The storage capacitor Cst charges the data signal applied to the control terminal of the driving transistor T2 and maintains it after the switching transistor T1 is turned off.

The OLED has an anode connected to the output terminal of the driving transistor T2 and a cathode connected to the common voltage ELVSS. The OLED emits light by changing its intensity depending on an output current ILD, thereby displaying an image.

The switching transistor T1 and the driving transistor T2 can be n-channel electric field effect transistors (FET) or p-channel electric field effect transistors. Also, the connection relation of the transistors T1 and T2, the storage capacitor Cst, and the OLED can be changed.

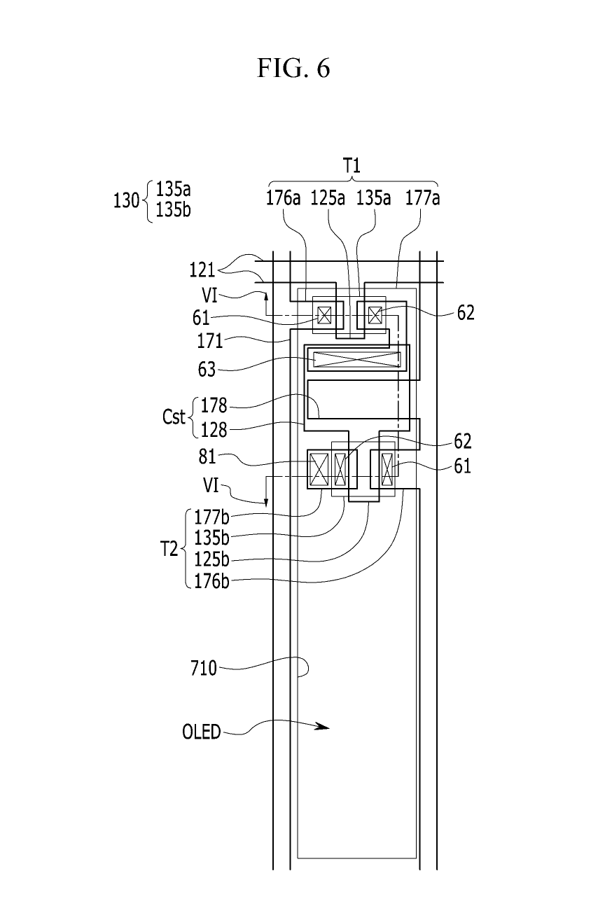

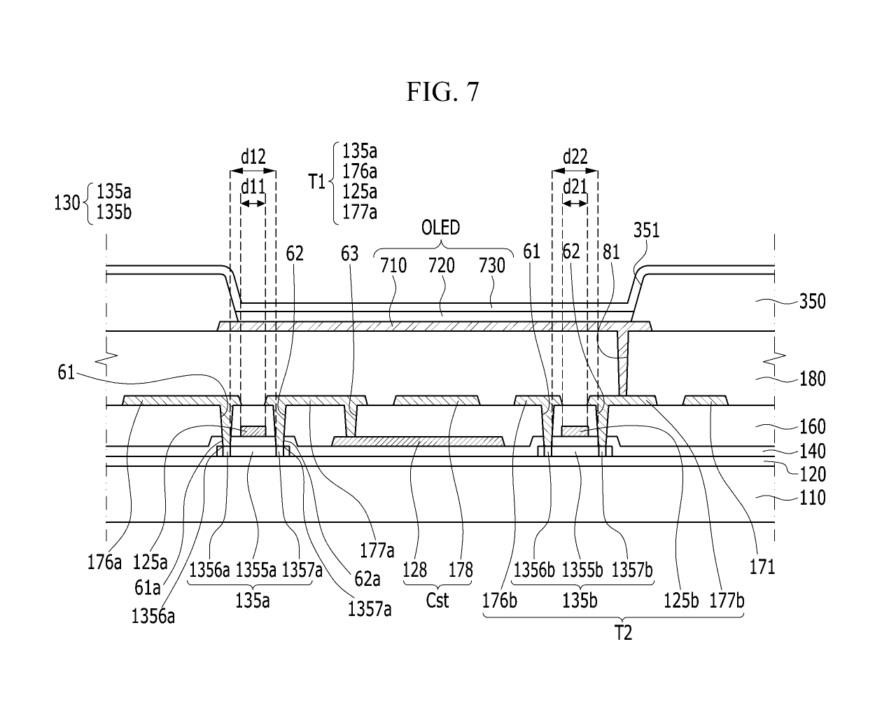

Next, the detailed structure of the pixel of the OLED display according to the exemplary embodiment shown in FIG. 5 will be described with reference to FIG. 6 and FIG. 7 as well as FIG. 5.

FIG. 6 is a detailed layout view of one pixel of an OLED display according to another exemplary embodiment. FIG. 7 is a cross-sectional view taken along a line VII-VII of FIG. 6.

As shown in FIG. 6 and FIG. 7, the OLED display includes a buffer layer 120 on a substrate 110. The substrate 110 can include an insulation substrate formed of glass, quartz, a ceramic material, or a plastic material. The buffer layer 120 can be formed to be a single layer of a silicon nitride (SiNx) or a dual layer structure in which a silicon nitride (SiNx) and a silicon oxide (SiOx) are laminated. The buffer layer 120 serves to prevent an unnecessary component such as impurity or moisture from being permeated and substantially simultaneously planarize a surface.

A semiconductor 130 is formed on the buffer layer 120. The semiconductor 130 includes a switching semiconductor or a switching semiconductor layer 135a and a driving semiconductor or a driving semiconductor layer 135b that are separated from each other. The semiconductors 135a and 135b can be formed of a polycrystalline semiconductor material or an oxide semiconductor material. The oxide semiconductor material can include any one oxide based on titanium (Ti), hafnium (Hf), zirconium (Zr), aluminum (Al), tantalum (Ta), germanium (Ge), zinc (Zn), gallium (Ga), tin (Sn), or indium (In), and indium-gallium-zinc oxide (InGaZnO4), indium-zinc oxide (Zn—In—O), zinc tin oxide (Zn—Sn—O), indium-gallium oxide (In—Ga—O), indium-tin oxide (In—Sn—O), indium-zirconium oxide (In—Zr—O), indium-zirconium-zinc oxide (In—Zr—Zn—O), indium-zirconium-tin oxide (In—Zr—Sn—O), indium-zirconium-gallium oxide (In—Zr—Ga—O), indium aluminum oxide (In—Al—O), indium-zinc-aluminum oxide (In—Zn—Al—O), indium-tin-aluminum oxide (In—Sn—Al—O), indium-aluminum-gallium oxide (In—Al—Ga—O), indium-tantalum oxide (In—Ta—O), indium-tantalum-zinc oxide (In—Ta—Zn—O), indium-tantalum-tin oxide (In—Ta—Sn—O), indium-tantalum-gallium oxide (In—Ta—Ga—O), indium-germanium oxide (In—Ge—O), indium-germanium-zinc oxide (In—Ge—Zn—O), indium-germanium-tin oxide (In—Ge—Sn—O), indium-germanium-gallium oxide (In—Ge—Ga—O), titanium-indium-zinc oxide (Ti—In—Zn—O), or hafnium-indium-zinc oxide (Hf—In—Zn—O) which is a compound oxide thereof. In the case when the semiconductor layer 131 is formed of the oxide semiconductor, in order to protect the oxide semiconductor that is vulnerable to an external environment such as a high temperature, a separate passivation layer can be added.

The switching semiconductor 135a are divided into a channel 1355a, source region 1356a and a drain region 1357a formed at respective sides of the channel 1355a. The driving semiconductor 135b are divided into a channel 1355b, a source region 1356b and a drain region 1357b formed at respective sides of the channel 1355b. The channel 1355a of the switching semiconductor 135a and the channel 1355b of the driving semiconductor 135b are channel-doped with a doping impurity of a N-type impurity or a P-type impurity. The source region 1356a and the drain region 1357a of the switching semiconductor 135a and the source region 1356b and the drain region 1357b of the driving semiconductor 135b are contact doping regions, or contact regions, that are contact-doped with the higher doping concentration of the doping impurity than the channel doping.

A gate insulating layer 140 is formed on the switching semiconductor 135a and the driving semiconductor 135b. The gate insulating layer 140 can be formed as the single layer or the multilayer formed of at least one of a silicon nitride and a silicon oxide.

A scan line 121, a driving gate electrode 125b, and a first storage capacitor plate 128 are formed on the gate insulating layer 140. The scan line 121 extends in the horizontal direction and transmits the scan signal Sn. A switching gate electrode 125a protrudes from the scan line 121 to the switching semiconductor 135a. The driving gate electrode 125b protrudes from the first storage capacitor plate 128 to the driving semiconductor 135b. The switching gate electrode 125a and the driving gate electrode 125b respectively overlap the switching and driving channels 1355a and 1355b.

An interlayer insulating layer 160 is formed on the scan line 121, the driving gate electrode 125b, and the first storage capacitor plate 128. The interlayer insulating layer 160 can be formed of a silicon nitride or a silicon oxide like the gate insulating layer 140.

The interlayer insulating layer 160 and the gate insulating layer 140 have a source contact hole 61 and a drain contact hole 62 respectively exposing the source region 1356 and the drain region 1357. The interlayer insulating layer 160 and the gate insulating layer 140 also have a storage contact hole 63 exposing a part of the first storage capacitor plate 128.

A data line 171 having a switching source electrode 176a, a driving voltage line 172 having a driving source electrode 176b and a second storage capacitor plate 178, a switching drain electrode 177a connected to the first storage capacitor plate 128, and a driving drain electrode 177b are formed on the interlayer insulating layer 160.

The data line 171 transmits the data signal Dm and extends in the direction crossing the gate line 121. The driving voltage line 172 transmits the driving voltage ELVDD, is separated from the data line 171, and extends in the same direction.

The switching source electrode 176a protrudes from the data line 171 toward the switching semiconductor 135a. The driving source electrode 176b protrudes from the driving voltage line 172 to the driving semiconductor 135b. The switching source electrode 176a and the driving source electrode 176b are respectively connected to the source regions 1356 through the source contact hole 61.

The switching drain electrode 177a faces the switching source electrode 176a and the driving drain electrode 177b faces the driving source electrode 176b. And the switching drain electrode 177a and the driving drain electrode 177b are respectively connected to the drain regions 1357 through the drain contact hole 62.

The source contact hole 61 exposing the source region 1356 and the drain contact hole 62 exposing the drain region 1357 are formed together in the gate insulating layer 140 and the interlayer insulating layer 160. The positions of the source contact hole 61 and the drain contact hole 62 respectively correspond to the positions of the source region 1356 and the drain region 1357. That is, lowest boundaries 61a and 62a of the source contact hole 61 and the drain contact hole 62 accord with uppermost boundaries 1356a and 1357a of the source region 1356 and the drain region 1357. Also, the switching gate electrode 125a and the driving gate electrode 125b do not have the structure in which the source region 1356 and the drain region 1357 are formed through a doping mask such that a length d11 of the switching gate electrode 125a and a length d12 of the switching channel 1355a are different from each other. Similarly, a length d21 of the driving gate electrode 125b and a length d22 of the driving channel 1355b are different from each other. That is, the length d11 is shorter than the length d12, and the length d21 is shorter than the length d22.

The switching drain electrode 177a extends and is electrically connected to the first storage capacitor plate 128 and the driving gate electrode 125b through the contact hole 63 formed in the interlayer insulating layer 160.

The second storage capacitor plate 178 protrudes from the driving voltage line 171 and overlaps the first storage capacitor plate 128. Accordingly, the first storage capacitor plate 128 and the second storage capacitor plate 178 form the storage capacitor Cst using the interlayer insulating layer 160 as a dielectric material.

The switching semiconductor 135a, the switching gate electrode 125a, the switching source electrode 176a, and the switching drain electrode 177a form the switching transistor T1. The driving semiconductor 135b, the driving gate electrode 125a, the driving source electrode 176b, and the driving drain electrode 177b form the driving transistor T2.

A passivation layer 180 is formed on the switching source electrode 176a, the driving source electrode 176b, the switching drain electrode 177a, and the driving drain electrode 177b.

A pixel electrode 710 is formed on the passivation layer 180, and the pixel electrode 710 can be formed of a transparent conductive material such as indium tin oxide (ITO), indium zinc oxide (IZO), zinc oxide (ZnO), or indium oxide (In2O3), or a reflective metal such as lithium (Li), calcium (Ca), lithium fluoride/calcium (LiF/Ca), lithium fluoride/aluminum (LiF/Al), aluminum (Al), silver (Ag), magnesium (Mg), or gold (Au). The pixel electrode 710 is electrically connected to the driving drain electrode 177b through a contact hole 81 formed in the interlayer insulating layer 160 to become an anode of an OLED.

A pixel definition layer 350 is positioned on the passivation layer 180 and an edge of the pixel electrode 710. The pixel definition layer 350 has a pixel opening 351 exposing the pixel electrode 710. The pixel definition layer 180 can be formed of a resin such as polyacrylates or polyimides, a silica-based inorganic material, and the like.

An organic emission layer 720 is formed in the pixel opening 351 of the pixel definition layer 350. The organic emission layer 720 is formed as a multilayer including one or more of an emission layer, a hole-injection layer (HIL), a hole-transporting layer (HTL), an electron-transporting layer (ETL), and an electron-injection layer (EIL). In the case where the organic emission layer 720 includes all the layers, the hole-injection layer is positioned on the pixel electrode 710 which is an anode. Further, the hole-transporting layer, the emission layer, the electron-transporting layer, and the electron-injection layer can be sequentially laminated thereon.

The organic emission layer 720 can include a red organic emission layer emitting red light, a green organic emission layer emitting green light, and a blue organic emission layer emitting blue light. The red organic emission layer, the green organic emission layer, and the blue organic emission layer are respectively formed in a red pixel, a green pixel, and a blue pixel, thereby implementing a color image.

Further, the organic emission layer 720 can implement the color image by laminating the red organic emission layer, the green organic emission layer, and the blue organic emission layer together in the red pixel, the green pixel, and the blue pixel, and forming a red color filter, a green color filter, and a blue color filter for each pixel. As another example, white organic emission layers emitting white light are formed in all of the red pixel, the green pixel, and the blue pixel. A red color filter, a green color filter, and a blue color filter are formed for each pixel, thereby implementing the color image. In the case of implementing the color image by using the white organic emission layer and the color filters, a deposition mask for depositing the red organic emission layer, the green organic emission layer, and the blue organic emission layer on respective pixels, that is, the red pixel, the green pixel, and the blue pixel, does not need to be used.

The white organic emission layer described in another example can be formed by one organic emission layer, and includes a configuration in which a plurality of organic emission layers are laminated to emit white light. For example, the white organic emission layer includes a configuration which can emit white light by combining at least one yellow organic emission layer and at least one blue organic emission layer, a configuration which can emit white light by combining at least one cyan organic emission layer and at least one red organic emission layer, a configuration which can emit white light by combining at least one magenta organic emission layer and at least one green organic emission layer, and the like.

A common electrode 730 is formed on the pixel definition layer 350 and the organic emission layer 720. The common electrode 730 can be formed of a transparent conductive material such as indium tin oxide (ITO), indium zinc oxide (IZO), zinc oxide (ZnO), or indium oxide (In2O3), or a reflective metal such as lithium (Li), calcium (Ca), lithium fluoride/calcium (LiF/Ca), lithium fluoride/aluminum (LiF/Al), aluminum (Al), silver (Ag), magnesium (Mg), or gold (Au). The common electrode 730 becomes the cathode of the OLED. The pixel electrode 710, the organic emission layer 720, and the common electrode 730 can configure the OLED.

Next, the manufacturing method of the OLED display according to another exemplary embodiment will be described with reference to accompanying drawings.

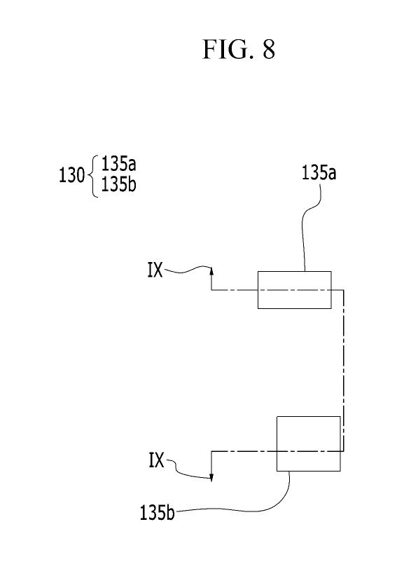

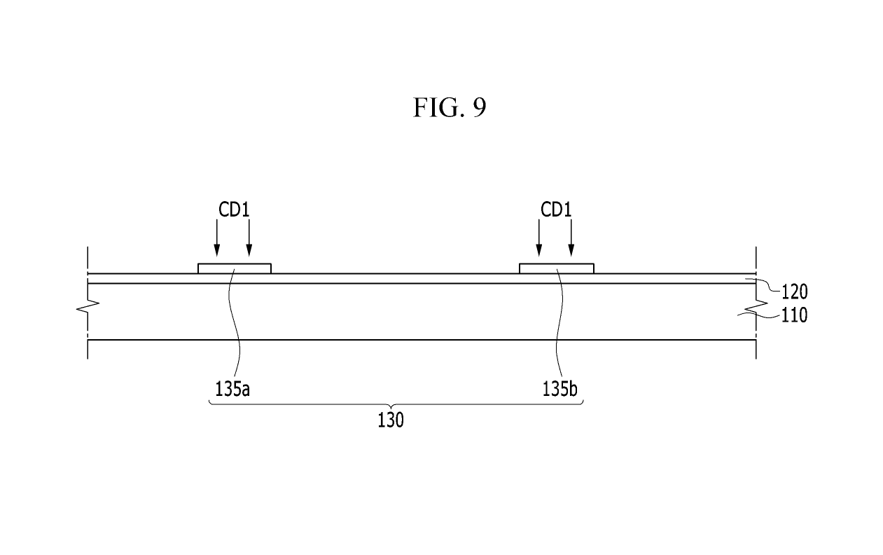

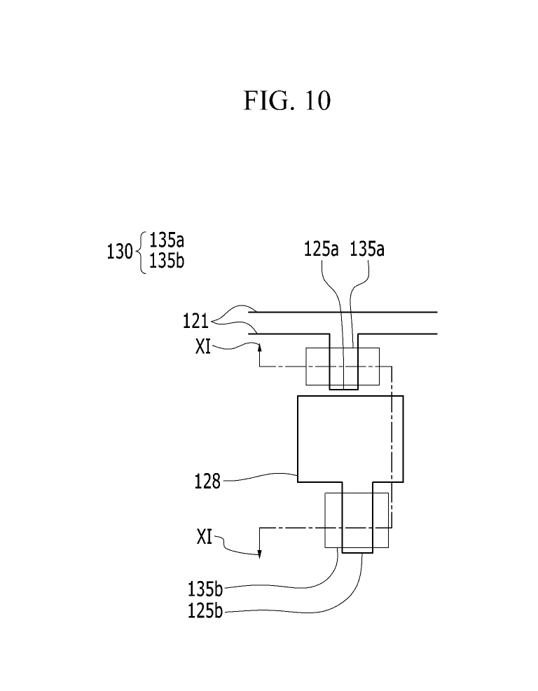

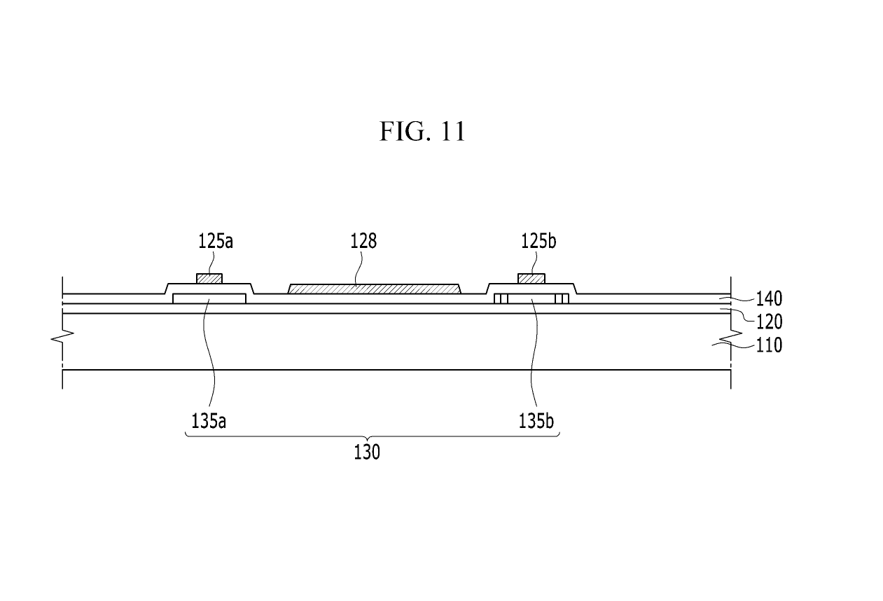

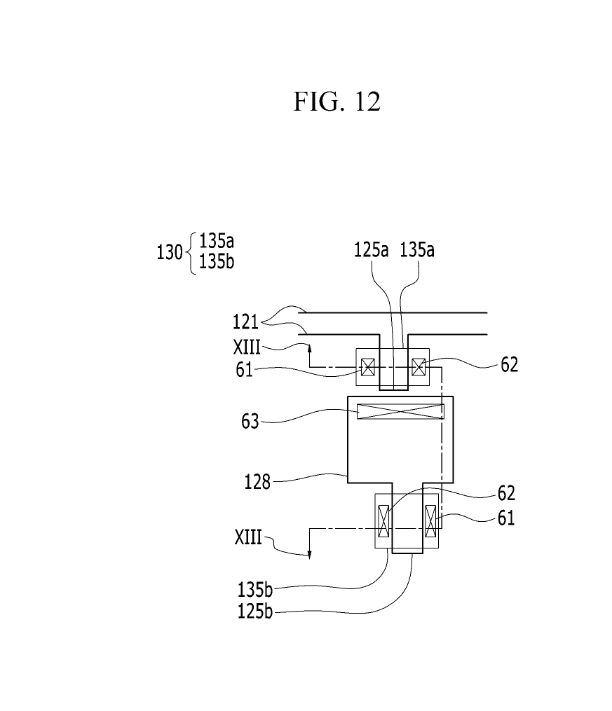

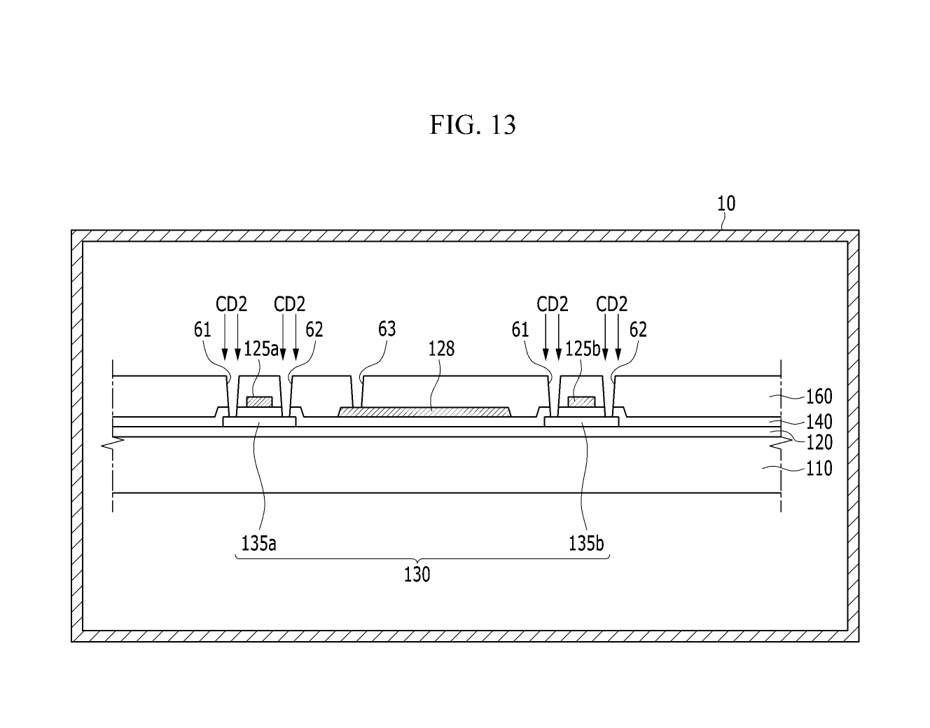

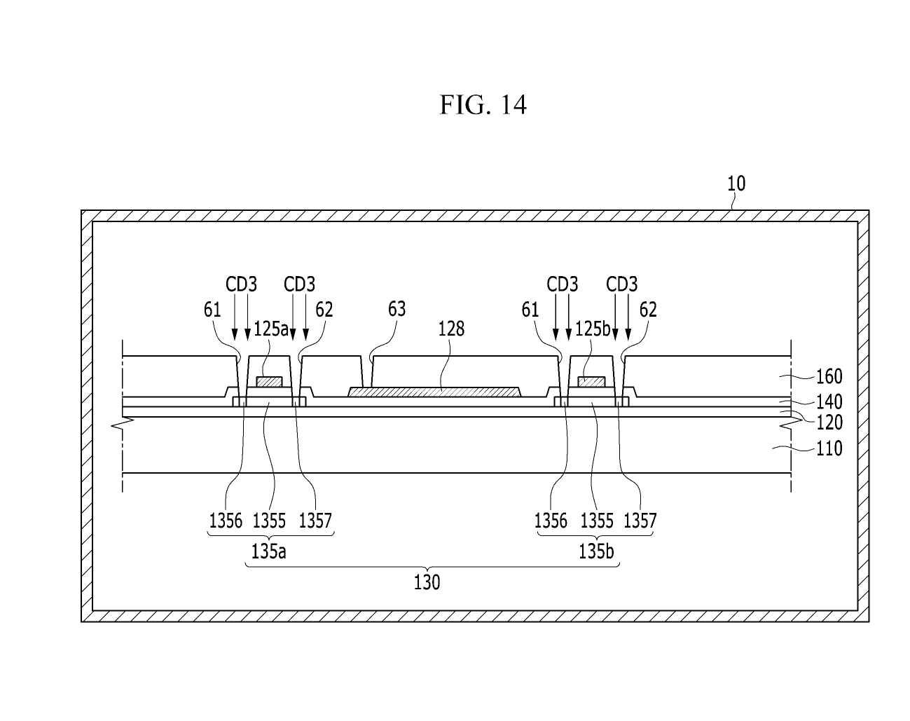

FIG. 8, FIG. 10, and FIG. 12 are layout views sequentially showing a manufacturing method of an OLED display according to an exemplary embodiment. FIG. 9 is a cross-sectional view of the OLED display of FIG. 8 taken along a line IX-IX. FIG. 11 is a cross-sectional view of the OLED display of FIG. 10 taken along a line XI-XI. FIG. 13 is a cross-sectional view of the OLED display of FIG. 12 taken along a line XIII-XIII. FIG. 14 is a cross-sectional view of the OLED display of FIG. 12 taken along a line XIII-XIII as a following step of FIG. 13.

First, as illustrated in FIG. 8 and FIG. 9, the buffer layer 120 is formed on the substrate 110. The buffer layer 120 can be formed of a single layer formed of a silicon nitride or a laminate layer of a silicon nitride and a silicon oxide. The buffer layer 120 is deposited on the entire surface of the substrate 110 by a method such as plasma enhanced chemical vapor deposition (PECVD). In addition, the semiconductor layer 131 is formed on the buffer layer 120. The semiconductor layer 131 can be formed of polysilicon or an oxide semiconductor, and the polysilicon can be formed by a method of forming an amorphous silicon layer and then crystallizing the layer. Various known methods can be applied as the crystallizing method, and for example, the amorphous silicon layer is crystallized by using heat, a laser, Joule heat, an electric field, a catalyst metal, or the like. By forming a photolithography process using a first mask on the polycrystalline semiconductor layer, the polycrystalline semiconductor layer is patterned into the switching semiconductor 135a and the driving semiconductor 135b of the shape shown in FIG. 8 and FIG. 9. In this case, since the switching semiconductor 135a and the driving semiconductor 135b are not doped, they are divided into the channel, the source region, and the drain region. Also, the switching semiconductor 135a and the driving semiconductor 135b are subjected to a channel doping process by an N type or a P type impurity. For example, the channel doping process is performed by the N type impurity or the P type impurity CD1 of the doping concentration about 2×10¹¹/cm³ and about 10 keV doping energy.

Next, as shown in FIG. 10 and FIG. 11, the gate insulating layer 140 covering the buffer layer 120, the switching semiconductor 135a, and the driving semiconductor 135b is formed thereon. The gate insulating layer 140 can be formed of a silicon nitride (SiNₓ), a silicon oxide (SiOx), or the like, and is deposited on an entire surface by a method such as plasma enhanced chemical vapor deposition (PECVD). A gate metal layer is deposited on the gate insulating layer 140. The gate metal layer is patterned by the photolithography process using a second mask. As a result, the gate wire including the scan line 121, the switching gate electrode 125a, the driving gate electrode 125b, and the first storage capacitive plate 128 is formed. The gate metal layer can be formed of a multilayer where a metal layer including any one of copper (Cu), a copper alloy, aluminum (Al), and an aluminum alloy, and a metal layer including any one of molybdenum (Mo) and a molybdenum alloy, are laminated.

Next, as shown in FIG. 12 and FIG. 13, the interlayer insulating layer 160 covering the gate insulating layer 140, the switching gate electrode 125a, the driving gate electrode 125b, and the first storage capacitive plate 128 is formed. The interlayer insulating layer 160 can be formed of a silicon nitride (SiNₓ), a silicon oxide (SiOx), or the like, and is deposited on the entire surface by a method such as plasma enhanced chemical vapor deposition (PECVD). The gate insulating layer 140 and the interlayer insulating layer 160 are patterned to form a plurality of contact holes 61, 62, and 63 by the photolithography process using a third mask. In this case, in the plasma processing device 10, the dry etching process is performed to form the contact holes 61, 62, and 63 with the fluorine series gas CD2. The fluorine series gas can be SF₆ or CF₆.

Next, as shown in FIG. 14, the contact doping process is performed to form the source region 1356 and the drain region 1357 in the part of the switching semiconductor 135a and the driving semiconductor 135b respectively exposed by the source contact hole 61 and the drain contact hole 62. In this case, in the plasma processing device 10 with which the dry etching process is performed, the ion doping process is performed to form the source region 1356 and the drain region 1357, and the compound CD3 of the Group 3 ions and the fluorine series gas is used. For example, the ion doping process is performed by BF₃ using Boron (B) as Group 3 ions.

As described above, in the same plasma processing device, by performing the dry etching process to form the contact hole and the ion doping process together to form the source region and the drain region, separate implantation can be omitted such that the manufacturing process can be simplified.

Next, as shown in FIG. 7 and FIG. 8, the data metal layer is formed on the interlayer insulating layer 160. The data metal layer can be formed of a multilayer where a metal layer formed of any one of copper, a copper alloy, aluminum, and an aluminum alloy, and a metal layer including any one of molybdenum and a molybdenum alloy, are laminated. In addition, the data metal layer is patterned by a photolithography process using a fourth mask. Thereby, on the interlayer insulating layer 160, the data wire including the data line 171 including the switching source electrode 176a, the switching drain electrode 177a, the driving voltage line 172 including the driving source electrode 176b, the driving drain electrode 177b, and the second storage capacitive plate 178 is formed. Also, the passivation layer 180 is formed on the interlayer insulating layer 160 and the contact hole 81 is formed in the passivation layer 180 by the photolithography process using a fifth mask, Further, a pixel electrode layer is formed on the protective layer 180, and patterned by the photolithography process using a sixth mask. Accordingly, a pixel electrode 710 connected to the driving drain electrode 177b through the contact hole 81 is formed on the passivation layer 180. The pixel definition layer 350 covering the pixel electrode 710 is formed on the passivation layer 180 and a pixel opening 351 exposing a part of the pixel electrode 191 is formed in the pixel definition layer 350 by using a seventh mask. The organic emission layer 720 is formed on the pixel electrode 191 exposed through the pixel opening 351 of the pixel definition layer 350. The OLED is completed by forming the common electrode 730 on the organic emission layer 720. The common electrode 730 is formed throughout the entire region including one the pixel definition layer 350, thereby omitting a separate mask.

A sealing member (not illustrated) for protecting the OLED can be formed on the common electrode 730 and sealed by a sealant on the substrate 110. The sealing member can be formed of various materials such as glass, quartz, ceramic, plastics, and metal. Meanwhile, a sealing thin film layer can be formed by depositing an inorganic layer and an organic layer on the common electrode 730 while not using the sealant.

While the inventive technology has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. An organic light-emitting diode (OLED) display, comprising:
a substrate;
a semiconductor layer formed over the substrate, wherein the semiconductor layer includes a channel and a contact region formed on opposing sides of the channel;
an insulating layer formed over the semiconductor layer and having a contact hole exposing the contact region; and
an OLED formed over the insulating layer,
wherein the OLED is electrically connected to the contact region through the contact hole, and
wherein at least a portion of the contact hole is formed directly above the contact region.

2. The OLED display of claim 1, wherein the contact hole has top and bottom portions opposing each other, wherein the contact region has top and bottom portions opposing each other, and wherein the bottom portion of the contact hole is connected to the top portion of the contact region.

3. The OLED display of claim 2, wherein the width of the bottom portion of the contact hole and the width of the top portion of the contact region are substantially the same.

4. The OLED display of claim 3, wherein the width of the contact hole gradually increases from the bottom portion to the top portion thereof.

5. The OLED display of claim 1, further comprising a driving gate electrode formed over the channel, wherein the channel includes a switching channel and a driving channel separated from each other,
wherein the insulating layer includes a gate insulating layer formed over the semiconductor layer and an interlayer insulating layer formed over the gate insulating layer,
wherein the driving gate electrode is formed between the gate insulating layer and the interlayer insulating layer and overlapping a portion of the driving channel, and
wherein the length of the driving gate electrode is less than the length of the driving channel.

6. The OLED display of claim 5, further comprising a switching gate electrode formed between the gate insulating layer and the interlayer insulating layer and overlapping a portion of the switching channel, wherein the length of the switching gate electrode is less than the length of the switching channel.

7. The OLED display of claim 1, further comprising a passivation layer formed over the interlayer insulating layer,
wherein the OLED includes i) a pixel electrode formed over the passivation layer and electrically connected to the semiconductor layer, ii) an organic emission layer formed over the pixel electrode, and iii) a common electrode formed over the organic emission layer.

8. A method of manufacturing an organic light-emitting diode (OLED) display, comprising:
forming a semiconductor layer over a substrate;
forming an insulating layer over the semiconductor layer;
etching the insulating layer so as to form a contact hole exposing a portion of the semiconductor layer; and
performing a contact doping process so as to form a contact region in a portion of the semiconductor layer exposed by the contact hole.

9. The method of claim 8, wherein the forming of the contact hole and the forming of the contact region are performed with the same plasma processing device.

10. The method of claim 9, wherein the etching is performed with a fluorine series gas in the plasma processing device, and wherein the contact doping process is performed with a compound of Group 3 ions and a fluorine series gas in the plasma processing device.

11. The method of claim 10, wherein at least a portion of the contact hole is formed directly above the contact region.

12. The method of claim 8, further comprising performing a channel doping process so as to form the channel in the semiconductor layer after forming the semiconductor layer.

13. The method of claim 8, wherein the contact hole has top and bottom portions opposing each other, wherein the contact region has top and bottom portions opposing each other, and wherein the bottom portion of the contact hole is connected to the top portion of the contact region.

14. The OLED display of claim 13, wherein the width of the bottom portion of the contact hole and the width of the top portion of the contact region are substantially the same.

15. The OLED display of claim 13, wherein the width of the contact hole gradually increases from the bottom portion to the top portion thereof.

16. An organic light-emitting diode (OLED) display, comprising:
a substrate;
a driving transistor including i) a driving semiconductor layer formed over the substrate and including a driving channel having two lateral ends and ii) a driving contact region formed adjacent to the lateral ends;
an insulating layer formed over the driving semiconductor layer and having a driving contact hole extending from the driving contact region; and
an OLED formed over the insulating layer and electrically connected to the driving contact region through the driving contact hole.

17. The display of claim 16, wherein at least a portion of the contact hole is formed directly above the contact region.

18. The display of claim 16, further comprising a switching transistor including i) a switching semiconductor layer formed over the substrate and including a switching channel having two lateral ends and ii) a switching contact region formed adjacent to the lateral ends, wherein the switching transistor is electrically connected to the driving transistor.

19. The display of claim 18, wherein the driving and switching contact holes each has top and bottom portions opposing each other, wherein the driving and switching contact regions each has top and bottom portions opposing each other, wherein the bottom portions of the contact holes are respectively connected to the top portions of the contact regions, and wherein the widths of the bottom portions of the contact holes and the widths of the top portions of the contact regions are substantially the same, respectively.

20. The display of claim 18, wherein each of the widths of the driving and switching channels is respectively greater than each of the widths of the driving and switching gate electrodes.
